(19) United States
(12) Patent Application Publication
(10) Pub. No.: US 2023/0315157 A1
(43) Pub. Date: Oct. 5, 2023

(54) MOISTURE REMOVAL FROM DEVICE PORT

(71) Applicant: Lenovo (United States) Inc., Morrisville, NC (US)

(72) Inventors: Nathan Peterson, Oxford, NC (US); Gary D Cudak, Wake Forest, NC (US); John M Petersen, Wake Forest, NC (US)

(21) Appl. No.: 17/708,455

(22) Filed: Mar. 30, 2022

(51) Int. Cl. G06F 1/16; H05K 7/20

(52) U.S. Cl. CPC G06F 1/1656; H05K 7/20

(57) ABSTRACT

One embodiment provides a method, including: detecting, using a moisture removal system, moisture at a port of an information handling device; and activating, using the moisture removal system, at least one moisture removal device located in proximity to the port of the information handling device. Other aspects are described and claimed.

### BACKGROUND

Information handling devices commonly contain at least one port permitting the connection of an external source to the device. For example, a device that uses a rechargeable battery will have a port located on the outer portion of the device that can accept a charging cable. Different types of connections will have a different port shape, all of which are located on the outer portion of the device. Traditionally, each port on a device remains open at all times, and, since the port is located on the external portion of the device, it is common for a foreign substance to enter a port on an information handling device.

### BRIEF SUMMARY

In summary, one aspect provides a method, including: detecting, using a moisture removal system, moisture at a port of an information handling device; and activating, using the moisture removal system, at least one moisture removal device located in proximity to the port of the information handling device

Another aspect provides an information handling device, including: at least one moisture removal device; a processor; a memory device that stores instructions executable by the processor: detect moisture at a port of the information handling device; and activate the at least one moisture removal device located in proximity to the port of the information handling device.

A further aspect provides a product, including: a storage device that stores code, the code being executable by a processor and, wherein executed by the processor, cause the product to: detect moisture at a port of an information handing device; and activate at least one moisture removal device located in proximity to the port of the information handling device.

The foregoing is a summary and thus may contain simplifications, generalizations, and omissions of detail; consequently, those skilled in the art will appreciate that the summary is illustrative only and is not intended to be in any way limiting.

For a better understanding of the embodiments, together with other and further features and advantages thereof, reference is made to the following description, taken in conjunction with the accompanying drawings. The scope of the invention will be pointed out in the appended claims.

### BRIEF DESCRIPTION OF THE SEVERAL VIEWS OF THE DRAWINGS

FIG. 1 illustrates an example of information handling device circuitry.

FIG. 2 illustrates another example of information handling device circuitry.

FIG. 3 illustrates an example method of activating a moisture removal device located in proximity to the port of the device in response to detecting moisture in the port.

### DETAILED DESCRIPTION

It will be readily understood that the components of the embodiments, as generally described and illustrated in the figures herein, may be arranged and designed in a wide variety of different configurations in addition to the described example embodiments. Thus, the following more detailed description of the example embodiments, as represented in the figures, is not intended to limit the scope of the embodiments, as claimed, but is merely representative of example embodiments.

Reference throughout this specification to “one embodiment” or “an embodiment” (or the like) means that a particular feature, structure, or characteristic described in connection with the embodiment is included in at least one embodiment. Thus, the appearance of the phrases “in one embodiment” or “in an embodiment” or the like in various places throughout this specification are not necessarily all referring to the same embodiment.

Furthermore, the described features, structures, or characteristics may be combined in any suitable manner in one or more embodiments. In the following description, numerous specific details are provided to give a thorough understanding of embodiments. One skilled in the relevant art will recognize, however, that the various embodiments can be practiced without one or more of the specific details, or with other methods, components, materials, et cetera. In other instances, well known structures, materials, or operations are not shown or described in detail to avoid obfuscation.

The most common foreign substance to make its way into the port of a device is water or other liquids. Whether an owner of a device spills a glass of water on the device, gets caught in the rain with the device in their pocket, or drops their device in the ocean, the introduction of water to a device can arise in many situations. As devices have become more secure, keeping the inner workings as protected from external influences as possible, devices have been able to gradually withstand water, and other foreign substances, for extended periods of time. However, the presence of one or more ports opened through an outer portion of a device, will always permit water to enter the port unless the port is covered. However, covers are generally only provided on a case that is used to cover the device. Not all cases include covers that cover all ports of a device. Additionally, not all users like covers on the device. Finally, covers on the ports can be a nuisance and after many uses can break or tear and fall off.

When water is detected to have entered a port on a device, some devices utilize a method of notifying the user of the device that water is present in a port. Upon detection of the water, the device may provide a notification on the display of the device individually or in combination with an audible and/or haptic feedback response. For example, a user's smartphone may detect that water is present in the charging port, and in response to the detection provide a message on the display of the smartphone along with a chime drawing the attention of the user to the smartphone.

After determining the device port, and potentially the entire device, has been exposed to water, a conventional solution suggested by many is to place the device in a bag of rice for a period of time. The rice is said to attract and absorb a certain amount of water from the phone, potentially drying out the device and permitting use of a once damaged device. The amount of time that a device must be left in the bag of rice is not standard but is understood to be a lengthy process (e.g., multiple hours in the bag of rice). Though this process of putting a water-exposed device into a bag of rice may dry out and thereafter permit use of the device, since rice is small and grainy, and breaks down into powders easily, rice can get inside of an open port on the device and damage the device, as well. What is needed is a method of drying out a device port without the introduction of rice or another foreign substance.

Accordingly, the system provides a method for dying moisture detected at the port of an information handling device by use of a moisture removal system implemented in the information handling device. A moisture removal system consisting of at least one moisture removal device may be located within proximity to a port of the device. After detection of the moisture within the port, a moisture removal device may be activated by the moisture removal system to dry-out and/or remove the moisture from the port. The use of a moisture removal system to remove such a foreign substance provides a system and method that may restore a component of the device without the introduction of another foreign substance (e.g., rice) to the device. Additionally, the system and method utilizing the moisture removal system will not potentially further damage a device, as is a possibility with the use of traditional drying methods. In other words, the moisture removal device of the described system and activated by the moisture removal system to remove the moisture, performs a moisture removal technique in a non-invasive manner unlike conventional techniques.

The illustrated example embodiments will be best understood by reference to the figures. The following description is intended only by way of example, and simply illustrates certain example embodiments.

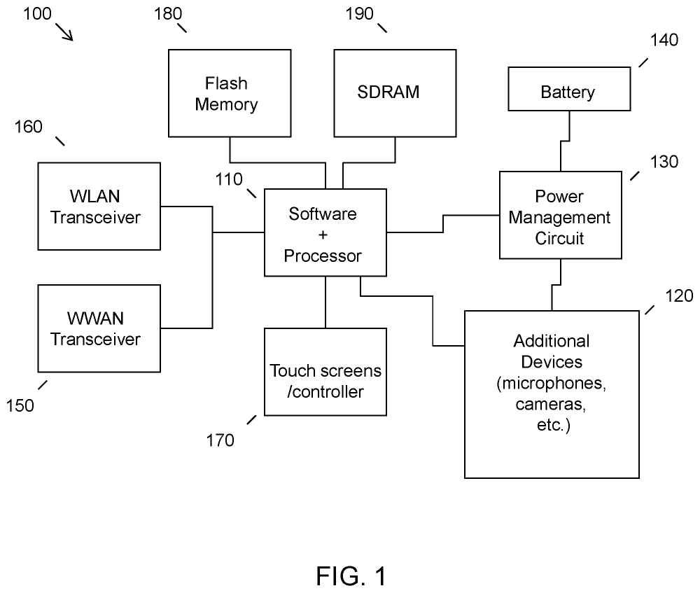

While various other circuits, circuitry or components may be utilized in information handling devices, with regard to smart phone and/or tablet circuitry 100, an example illustrated in FIG. 1 includes a system on a chip design found for example in tablet or other mobile computing platforms. Software and processor(s) are combined in a single chip 110. Processors comprise internal arithmetic units, registers, cache memory, busses, input/output (I/O) ports, etc., as is well known in the art. Internal busses and the like depend on different vendors, but essentially all the peripheral devices (120) may attach to a single chip 110. The circuitry 100 combines the processor, memory control, and I/O controller hub all into a single chip 110. Also, systems 100 of this type do not typically use serial advanced technology attachment (SATA) or peripheral component interconnect (PCI) or low pin count (LPC). Common interfaces, for example, include secure digital input/output (SDIO) and inter-integrated circuit (I2C).

There are power management chip(s) 130, e.g., a battery management unit, BMU, which manage power as supplied, for example, via a rechargeable battery 140, which may be recharged by a connection to a power source (not shown). In at least one design, a single chip, such as 110, is used to supply basic input/output system (BIOS) like functionality and dynamic random-access memory (DRAM) memory.

System 100 typically includes one or more of a wireless wide area network (WWAN) transceiver 150 and a wireless local area network (WLAN) transceiver 160 for connecting to various networks, such as telecommunications networks and wireless Internet devices, e.g., access points. Additionally, devices 120 are commonly included, e.g., a wireless communication device, external storage, etc. System 100 often includes a touch screen 170 for data input and display/rendering. System 100 also typically includes various memory devices, for example flash memory 180 and synchronous dynamic random-access memory (SDRAM) 190.

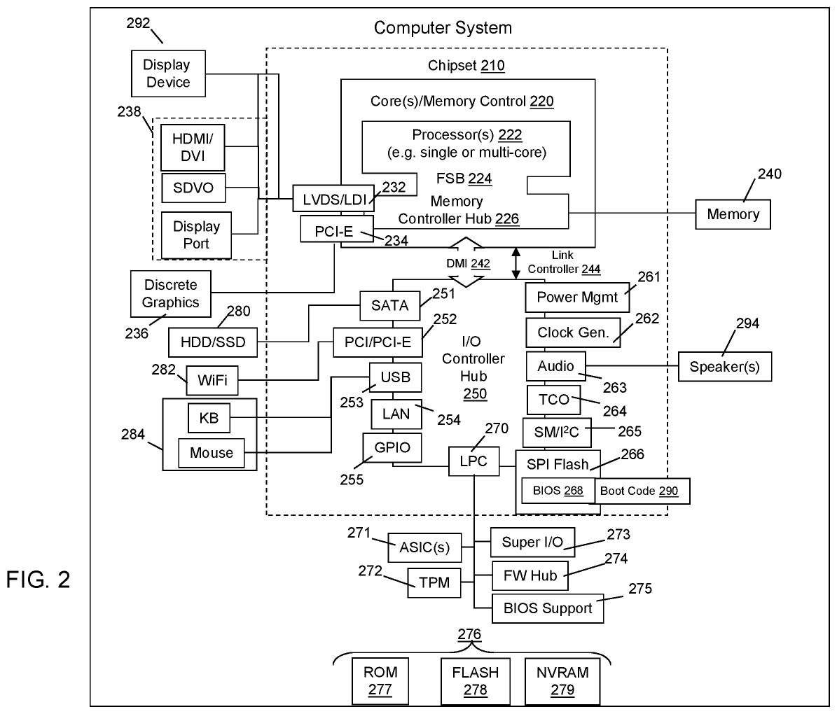

FIG. 2 depicts a block diagram of another example of information handling device circuits, circuitry or components. The example depicted in FIG. 2 may correspond to computing systems such as personal computers, or other devices. As is apparent from the description herein, embodiments may include other features or only some of the features of the example illustrated in FIG. 2.

The example of FIG. 2 includes a so-called chipset 210 (a group of integrated circuits, or chips, that work together, chipsets) with an architecture that may vary depending on manufacturer. The architecture of the chipset 210 includes a core and memory control group 220 and an I/O controller hub 250 that exchanges information (for example, data, signals, commands, etc.) via a direct management interface (DMI) 242 or a link controller 244. In FIG. 2, the DMI 242 is a chip-to-chip interface (sometimes referred to as being a link between a “northbridge” and a “southbridge”). The core and memory control group 220 include one or more processors 222 (for example, single or multi-core) and a memory controller hub 226 that exchange information via a front side bus (FSB) 224; noting that components of the group 220 may be integrated in a chip that supplants the conventional “northbridge” style architecture. One or more processors 222 comprise internal arithmetic units, registers, cache memory, busses, I/O ports, etc., as is well known in the art.

In FIG. 2, the memory controller hub 226 interfaces with memory 240 (for example, to provide support for a type of random-access memory (RAM) that may be referred to as “system memory” or “memory”). The memory controller hub 226 further includes a low voltage differential signaling (LVDS) interface 232 for a display device 292 (for example, a cathode-ray tube (CRT), a flat panel, touch screen, etc.). A block 238 includes some technologies that may be supported via the low-voltage differential signaling (LVDS) interface 232 (for example, serial digital video, high-definition multimedia interface/digital visual interface (HDMI/DVI), display port). The memory controller hub 226 also includes a PCI-express interface (PCI-E) 234 that may support discrete graphics 236.

In FIG. 2, the I/O hub controller 250 includes a SATA interface 251 (for example, for hard-disc drives (HDDs), solid-state drives (SSDs), etc., 280), a PCI-E interface 252 (for example, for wireless connections 282), a universal serial bus (USB) interface 253 (for example, for devices 284 such as a digitizer, keyboard, mice, cameras, phones, microphones, storage, other connected devices, etc.), a network interface 254 (for example, local area network (LAN)), a general purpose I/O (GPIO) interface 255, a LPC interface 270 (for application-specific integrated circuit (ASICs) 271, a trusted platform module (TPM) 272, a super I/O 273, a firmware hub 274, BIOS support 275 as well as various types of memory 276 such as read-only memory (ROM) 277, Flash 278, and non-volatile RAM (NVRAM) 279), a power management interface 261, a clock generator interface 262, an audio interface 263 (for example, for speakers 294), a time controlled operations (TCO) interface 264, a system management bus interface 265, and serial peripheral interface (SPI) Flash 266, which can include BIOS 268 and boot code 290. The I/O hub controller 250 may include gigabit Ethernet support.

The system, upon power on, may be configured to execute boot code 290 for the BIOS 268, as stored within the SPI Flash 266, and thereafter processes data under the control of one or more operating systems and application software (for example, stored in system memory 240). An operating system may be stored in any of a variety of locations and accessed, for example, according to instructions of the BIOS 268. As described herein, a device may include fewer or more features than shown in the system of FIG. 2.

Information handling device circuitry, as for example outlined in FIG. 1 or FIG. 2, may be used in devices such as tablets, smart phones, personal computer devices generally, and/or electronic devices, which may be used in systems to detect and remove moisture from a port of a device. For example, the circuitry outlined in FIG. 1 may be implemented in a tablet or smart phone embodiment, whereas the circuitry outlined in FIG. 2 may be implemented in a personal computer embodiment.

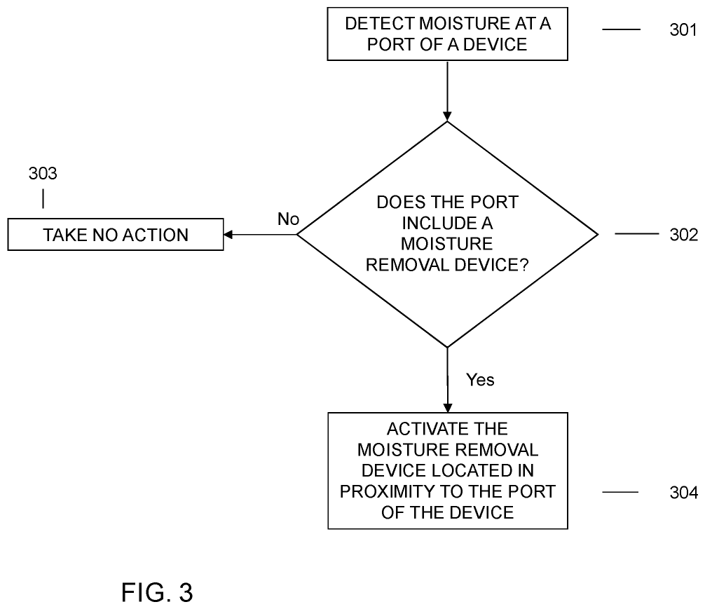

FIG. 3 illustrates an example method of activating a moisture removal device located in proximity to the port of the device in response to detecting moisture in the port. The method may be implemented on a system which includes a processor, memory device, output devices (e.g., display device, etc.), input devices (e.g., keyboard, touch screen, mouse, microphones, sensors, etc.), image capturing devices, and/or other components, for example, those discussed in connection with FIG. 1 and/or FIG. 2. While the system may include known hardware and software components and/or hardware and software components developed in the future, the system itself is specifically programmed to perform the functions as described herein to detect and remove moisture at the port of a device. Additionally, the moisture removal system includes modules and features that are unique to the described system.

At 301, the system may detect moisture present at the port of a user device, also referred to as an information handling device, for example, a tablet, smart phone, smart watch, laptop, personal computer, digital assistant device, navigation system, activity tracker, and/or the like. The detection of moisture may be performed by a moisture removal system. The moisture removal system may utilize a method to determine moisture is present at a port of the device. One technique for detecting moisture at the port is through the use of a second device or accessory. For example, the moisture removal system may determine that when a user is attempting to plug in a cord or accessory into a port, water is detected by the second device or accessory or is detected by the device when the moisture is moved by the second device or accessory being inserted into the port. Additionally, or alternatively, one or more sensors may be present in a connecter accessing a port that may detect moisture within a port. For example, a charging wire that is plugged into a power source may contain a sensor on a portion of the tip that may be inserted into a charging port. Then, after connection of the charger to the device through the charging port, the sensor of the connector may detect moisture within the port of the device and convey this information to the device.

While the example of a charging port and charging cable will be used here throughout, it should be understood that the described system can be applied to any port of the device, for example, an HDMI port, an SD (secure digital) card port, an ethernet port, a microphone jack port, a SIM (subscriber identification module) card port, and the like.

The detection of moisture at a port of a device, at 301, may be performed by the use of one or more sensors coupled to the device and/or moisture removal system. A sensor present within a port may detect the presence of moisture, and upon this detection, notify a user of the moisture present and/or automatically move forward with attempting to remove the moisture from the port. The moisture removal system implemented in a device may further utilize additional sensors present within the device to assist with the detection of moisture. For example, a touch sensor may recognize a substance is present in a location and the substance is not a human finger. If the touch sensor is located in close proximity to a charging port, the system may use this information to assist in detecting whether moisture is present at a port.

Additionally, when detecting moisture at the port of the device, the moisture removal system may detect water at the port immediately upon the introduction water on the device. In other words, the moisture removal system may not have to wait until connection at the port or detection of the moisture at the port to determine that moisture is present at a port of the device. For example, if the device determines that moisture is present at a particular location or a plurality of locations of the device, the device may infer that moisture is present at the port, even without direct detection. It should be understood that the described techniques for detecting moisture are merely examples, and other moisture detection techniques are possible and contemplated.

Upon detecting moisture is present at the port, a notification may be provided to the user indicating the detection of moisture at a port. The notification may be a visual notification provided on the display of a user device. Additionally, or alternatively, the system may provide an audible notification notifying the user of the detection of moisture in a port. For example, a notification tone may be associated with the detection of moisture may sound off when moisture is detected. The notification may also identify what port the moisture was detected. The notification may remain visible until moisture is no longer detected at the port.

After detecting moisture at a port, at 301, the moisture removal system may determine whether the port with the detected moisture includes a moisture removal device at 302 or if a moisture removal device is in proximity to the port. To determine if there is a moisture removal device in or within proximity to the port, the system may access details of the device. Generally, a device will know what components are included within the device, including a moisture removal device. In the event that the device is not equipped with a moisture removal device, the system may determine if a moisture removal device is in proximity to the port. This may be performed using one or more communication mediums, for example, near-field communication, wired communication, wireless communication, network communication, and/or the like. In an embodiment, when it is determined that there is not a moisture removal device associated with the port determined to have moisture, the system may take no action other than the display of the notification at 303. The notification may also indicate conventional techniques for addressing moisture in a device.

However, when it is determined, at 302, that the port of the device does include a moisture removal device, the system may, at 304, activate the moisture removal device located in proximity to the port of the device. It should be noted that the term proximity refers to moisture removal devices located within or at the port of the device and also moisture removal device located near the port but not touching the port. Activation of the moisture removal device may occur responsive to a request or confirmation of the user. For example, the moisture removal system may query the user about whether the user would like to activate the moisture removal device, for example, via a notification provided on a display of the device. If the user authorizes the activation of the moisture removal device, the system may proceed with activating the moisture removal device. Additionally, or alternatively, after the detection of moisture at the port at 301, and determining that a moisture removal system associated with the port is present at 302, the system may automatically activate the moisture removal device located in proximity to the port of the device at 304. It should be noted that activation and engagement of the moisture removal device is a relatively short process, for example, the moisture removal device may be active for five or ten minutes or until the moisture is no longer detected, which is a much shorter process with the moisture removal device than the conventional hours in a bag of rice technique.

The moisture removal device of an information handling device present in proximity to a port of the information handling device may perform a function for drying out and/or removing moisture from the port. A moisture removal device may be a component of the moisture removal system. Communication between the moisture removal device at a port and the moisture removal system may permit the detection of the moisture at the device, and thereafter, the activation of the moisture removal device. One moisture removal device may warm an element present in proximity to the port of the device in order to remove the moisture. Warming an element in proximity to the device may promote the drying out of a port based on natural environmental processes. For example, it is known that heat may dry out and/or remove moisture (e.g., evaporation) when applied to moisture. Thus, the application or activation of heat on an element present in proximity to the port of the device containing moisture may be applied in an attempt to remove the moisture.

In order to warm the moisture removal device element of the port, the system may provide power to the moisture removal device to assist with the drying out of a port. The system may provide, for example, less than 1 watt of power, to provide enough heat to dry out a port, but not so much heat that would cause damage to the port, device, connections, the user, and/or the like. The element being warmed may be wrapped around or located on a portion of the inner wall of the port. For example, a heat strip may line or be located within the inside of a port, and upon activating the moisture removal device, the heat strip in this example, the heat strip lining will become warm and warm the inside of the port to assist with removing the moisture. The heat strip and/or any other warming element utilized, may be integrated into the housing of the device surrounding the port. Therefore, the warming element may be present within the device but is still in proximity to the port and, when activated, provides enough heat to dry out the port.

Other heat elements may be utilized and a heat strip is not intended to be limiting. For example, the system may utilize a heat coil as the moisture removal device associated with a port. Similar to the implementation of the heat strip as a moisture removal device, the heat coil may be located in proximity to, which may include within, a port and assist with removal of moisture. As another example, a bare wire (e.g., copper wire) may be integrated into a device. For devices that do not originally have a moisture removal device integrated into the user device, an external wire, for example, in the form of a connector to be plugged into the port other than an intended connector (e.g., charging connector, microphone connector, etc.), may be connected and heated to warm the port. This external wire can have the correct connector type corresponding to the port, but instead of performing the intended function of the port, the external wire can instead apply heat to the port.

The moisture removal system may utilize heat routinely generated by a device and/or component within proximity to the device. In other words, the moisture removal device may be external to the device itself. For example, when charging a device, since a current is being generated, heat is naturally generated. In the system, this naturally generated heat may provide enough heat in order to remove moisture from a port. Thus, upon connecting a device to a charging wire producing current, the system may determine that the moisture removal device to activate may simply be the charging process that generates this low-level heat.

Traditionally, charging wires are coupled to the device by being inserted into the charging port of the device. In this charging orientation, when there is a presence of moisture detected at a port of the device, the charging wire may then be exposed to the moisture present in the port. Thus, the charging wire, or other connector connected to the port, now has moisture on the connector. Thus, the charging wire, or other connector, may similarly utilize the heat generated as a warming element, and thereafter, remove moisture present on the connected connector. As mentioned previously, the use of a charging wire is intended to be non-limiting. For example, if an HDMI port is in use and moisture is detected in the port, the system may utilize the heat generated by the connection of an HDMI cable to a display to assist in removing moisture from the HDMI port, and potentially, from the HDMI wire connecting the device to a display.

Wireless charging also generates a level of heat that may be utilized by a moisture removal system to assist in removing moisture from a port. This external device can be used to remove moisture from a port. When the device is in proximity to the wireless charger, or other external device that produces heat, the heat generated from the wireless charger, or other device, may be enough to dry out a port present on a user device. For example, similar to how a traditional charging connection generates heat, a wireless charger may generate heat, as well. However, in this configuration, since there is no connection of a connector into the port, air flow in the port may further assist with moisture removal.

A situation for a user may arise in which the moisture removal system may detect moisture at a port of the device and may be unable to activate a moisture removal device. For example, the battery of the device may be dead or close to and, therefore, unable to be used to power a moisture removal device. Rather than draining a battery of the device when attempting to provide a charge to a moisture removal device located in proximity to the port containing moisture, the system may utilize a technique that can maintain battery life while also removing the moisture from the port. One technique is the use of the charging methods previously mentioned since the device would be charging while generating heat. Additionally, or alternatively, the charge accepted from a charging wire or a wireless charger may power a warming element, such as a heat strip present in the charging port. Thus, the charging techniques utilized by the moisture removal system may use the natural heat generated by the current flow or may power a warming element in proximity to the port instead of using the battery of the device.

Additionally, or alternatively, when a device is determined to be in a low-battery mode, the warming element of a moisture removal device associated with a port may be pulsed to generate localized gas expansion and reduction. Such a technique may apply a burst of energy to a warming element that will heat up gases present in a port causing the particles to expand, therefore removing water vapor that was previously present in the port. It is established that heating up water will transition water from a liquid state to a gaseous state, and upon the transitioning of states, water may be removed from an area in more than one way. A short burst of heat may be enough to expand moisture to a gaseous state, and after transitioning states and deactivating the charge, the air within the port may be cycled out for new, drier air. This air cycling process may be performed until moisture is determined to be removed from the port. Additionally, or alternatively, a system may routinely perform this air cycling technique to ensure that moisture is not present within a port.

A device may have multiple moisture removal devices or moisture removal techniques that can be utilized to remove moisture within a port. For example, a single port may have multiple moisture removal devices (e.g., a heat strip integrated into the port, a moisture removal device within proximity to the port, etc.), a single port may have a single moisture removal device that can utilize multiple techniques (e.g., a heat strip that can be pulsed, a heat strip that can have a continuous current applied, etc.), multiple ports that each have a single moisture removal device and technique, multiple ports having multiple moisture removal devices or techniques, a combination thereof, and/or the like. In this case, the moisture removal system may determine which of the moisture removal devices to activate in response to detection of the moisture. The determination may also include activating more than one moisture removal device. Determining which moisture removal device, or devices, to activate may be based upon one or more factors, for example, user preference, speed of moisture removal, device battery life, which port has the detected moisture, and/or the like.

The various embodiments described herein thus represent a technical improvement to conventional methods of removing moisture from a port of an information handling device. Rather than using the traditional method of placing a device in a bag of rice, potentially further damaging the device, the described system and method utilizes a moisture removal system consisting of a moisture removal device located in proximity to the port containing moisture to remove the moisture from the port in a secure manner. The system is able to utilize one or more methods to remove the moisture from the port of the device without the influence of additional foreign substances or invasive methods that may potentially further damage a device. Additionally, the system may perform the removal of moisture from the device automatically upon detection of the presence of the moisture, which may further assist a user in maintaining a positive device health. Such embodiments may allow a system to quickly remove any moisture detected from a port of the device in an attempt to minimize the damage to an information handling device.

As will be appreciated by one skilled in the art, various aspects may be embodied as a system, method or device program product. Accordingly, aspects may take the form of an entirely hardware embodiment or an embodiment including software that may all generally be referred to herein as a “circuit,” “module” or “system.” Furthermore, aspects may take the form of a device program product embodied in one or more device readable medium(s) having device readable program code embodied therewith.

It should be noted that the various functions described herein may be implemented using instructions stored on a device readable storage medium such as a non-signal storage device that are executed by a processor. A storage device may be, for example, a system, apparatus, or device (e.g., an electronic, magnetic, optical, electromagnetic, infrared, or semiconductor system, apparatus, or device) or any suitable combination of the foregoing. More specific examples of a storage device/medium include the following: a portable computer diskette, a hard disk, a random-access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a storage device is not a signal and “non-transitory” includes all media except signal media.

Program code embodied on a storage medium may be transmitted using any appropriate medium, including but not limited to wireless, wireline, optical fiber cable, RF, et cetera, or any suitable combination of the foregoing.

Program code for carrying out operations may be written in any combination of one or more programming languages. The program code may execute entirely on a single device, partly on a single device, as a stand-alone software package, partly on single device and partly on another device, or entirely on the other device. In some cases, the devices may be connected through any type of connection or network, including a local area network (LAN) or a wide area network (WAN), or the connection may be made through other devices (for example, through the Internet using an Internet Service Provider), through wireless connections, e.g., near-field communication, or through a hard wire connection, such as over a USB connection.

Example embodiments are described herein with reference to the figures, which illustrate example methods, devices and program products according to various example embodiments. It will be understood that the actions and functionality may be implemented at least in part by program instructions. These program instructions may be provided to a processor of a device, a special purpose information handling device, or other programmable data processing device to produce a machine, such that the instructions, which execute via a processor of the device implement the functions/acts specified.

It is worth noting that while specific blocks are used in the figures, and a particular ordering of blocks has been illustrated, these are non-limiting examples. In certain contexts, two or more blocks may be combined, a block may be split into two or more blocks, or certain blocks may be re-ordered or re-organized as appropriate, as the explicit illustrated examples are used only for descriptive purposes and are not to be construed as limiting.

As used herein, the singular “a” and “an” may be construed as including the plural “one or more” unless clearly indicated otherwise.

This disclosure has been presented for purposes of illustration and description but is not intended to be exhaustive or limiting. Many modifications and variations will be apparent to those of ordinary skill in the art. The example embodiments were chosen and described in order to explain principles and practical application, and to enable others of ordinary skill in the art to understand the disclosure for various embodiments with various modifications as are suited to the particular use contemplated.

Thus, although illustrative example embodiments have been described herein with reference to the accompanying figures, it is to be understood that this description is not limiting and that various other changes and modifications may be affected therein by one skilled in the art without departing from the scope or spirit of the disclosure.

What is claimed is:

1. A method, the method comprising:
detecting, using a moisture removal system, moisture at a port of an information handling device; and
activating, using the moisture removal system, at least one moisture removal device located in proximity to the port of the information handling device.

2. The method of claim 1, wherein the at least one moisture removal device comprises a heat strip.

3. The method of claim 1, wherein the activating comprises providing power to the at least one moisture removal device.

4. The method of claim 1, wherein the at least one moisture removal device is external to the information handling device.

5. The method of claim 1, wherein the activating comprises providing current pulses to the at least one moisture removal device.

6. The method of claim 5, wherein the providing current pulses is performed responsive to determining a battery level of a battery of the device is below a predetermined threshold.

7. The method of claim 1, comprising determining which of a plurality of moisture removal devices of the information handling device activate in response to detecting the moisture.

8. The method of claim 1, comprising displaying, on a display of the information handling device, a notification indicating the at least one moisture removal device is to be activated and wherein the activating occurs responsive to receiving user input authorizing the activation of the at least one moisture removal device.

9. The method of claim 1, wherein the at least one moisture removal device is located within the port.

10. The method of claim 1, wherein the port comprises a charging port.

11. An information handling device, comprising:
at least one moisture removal device;
a processor;
a memory device that stores instructions executable by the processor:
detect moisture at a port of the information handling device; and
activate the at least one moisture removal device located in proximity to the port of the information handling device.

12. The information handling device of claim 11, wherein the at least one moisture removal device comprises a heat strip.

13. The information handling device of claim 11, wherein the activating comprises providing power to the at least one moisture removal device.

14. The information handling device of claim 11, wherein the at least one moisture removal device is external to the information handling device.

15. The information handling device of claim 11, wherein the activating comprises providing current pulses to the at least one moisture removal device.

16. The information handling device of claim 15, wherein the providing current pulses is performed responsive to determining a battery level of a battery of the device is below a predetermined threshold.

17. The information handling device of claim 11, comprising determining which of a plurality of moisture removal devices the information handling device activate in response to detecting the moisture.

18. The information handling device of claim 11, comprising displaying, on a display of the information handling device, a notification indicating the at least one moisture removal device is to be activated and wherein the activating occurs responsive to receiving user input authorizing the activation of the at least one moisture removal device.

19. The information handling device of claim 11, wherein the at least one moisture removal device is located within the port.

20. A product, comprising:
a storage device that stores code, the code being executable by a processor and, wherein executed by the processor, cause the product to:
detect moisture at a port of an information handing device; and
activate at least one moisture removal device located in proximity to the port of the information handling device.
